(19) United States
(12) Patent Application Publication
(10) Pub. No.: US 2004/0120117 A1
(43) Pub. Date: Jun. 24, 2004

(54) Electronic package with improved thermal performance

(76) Inventors: Cheng-Why Tan, Penang (MY); Fu-Mauh Wong, Penang (MY)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/325,759

(22) Filed: Dec. 20, 2002

(51) Int. Cl. H05K 7/20

(52) U.S. Cl. 361/704; 361/707

(57) ABSTRACT

The present invention provides an electronic package with improved thermal performance. The electronic package includes a thermally conductive heat dissipator and a transmission circuit. The thermally conductive heat dissipator has a first surface and a second surface with the first surface of the thermally conductive heat dissipator including extended portions. The transmission circuit defines a cavity, and includes a first conductive layer, a second conductive layer, and a dielectric layer sandwiched between the first and second conductive layers. The second conductive layer is coupled to the second surface of the thermally conductive heat dissipator and the cavity extends through the transmission circuit to the thermally conductive heat dissipator.

### FIELD OF THE INVENTION

The technical field of this disclosure is electronic packages, particularly, electronic packages with improved thermal performance.

### BACKGROUND OF THE INVENTION

Electronic packages with semiconductor chips as part of the package are widely utilized and known throughout the electronics industry. One such electronic package is the tape ball grid array (TBGA) package. Electronic packages within this art include a semiconductor chip coupled to a first substrate that is further coupled to a second substrate such as a printed circuit board (PCB).

FIG. 1 is a schematic diagram of a conventional electronic package. Electronic package 100 includes a transmission circuit 105, a heat dissipation plate 110, a semiconductor device 120, a chip mounting cavity 130, and an adhesive layer 150. Transmission circuit 105 includes flexible dielectric layer 170 having a first conductive layer 140 on a first side, and a second conductive layer 145 on a second side. Electronic package 100 additionally includes coating 160, solder balls 180, and wirebond connections 190.

Referring to FIG. 1, heat dissipation plate 110 is bonded to transmission circuit 105 by an adhesive 150. The heat dissipation plate 110 is also referred to as a heat spreader. Chip mounting cavity 130 is defined by transmission circuit 105 and heat dissipation plate 110. Semiconductor device 120 is mounted on heat dissipation plate 110. The semiconductor device 120 is also referred to as a die. In one example, semiconductor device 120 is mounted on heat dissipation plate 110 utilizing adhesive. Semiconductor device 120 is mounted in chip mounting cavity 130 and is wirebonded directly to first conductive layer 140 utilizing wirebond connections 190. Semiconductor device 120 is also wirebonded to second conductive layer 145 (connection not shown).

Power and signal traces are typically provided in the first conductive layer 140. These traces are laid out and applied by one of several processes known in the art. Second conductive layer 145 functions as a ground or power reference plane having a constant voltage.

Heat removal from electronic packages is an important concern in the electronics industry. Combining greater transistor density with increased device performance increases heat generation within semiconductor devices. Heat build up in semiconductor devices causes problems such as transistor break down. It would be desirable, therefore, to provide an electronic package that would overcome these and other disadvantages.

### SUMMARY OF THE INVENTION

The present invention is directed to an electronic package with improved thermal performance. The invention allows an electronic package to transfer heat from the contents of the electronic package to the ambient atmosphere.

One aspect of the present invention provides an electronic package with improved thermal performance. The electronic package includes a thermally conductive heat dissipator and a transmission circuit. The thermally conductive heat dissipator has a first surface and a second surface with the first surface of the thermally conductive heat dissipator including extended portions. The transmission circuit defines a cavity, and includes a first conductive layer, a second conductive layer, and a dielectric layer sandwiched between the first and second conductive layers. The second conductive layer is coupled to the second surface of the thermally conductive heat dissipator and the cavity extends through the transmission circuit to the thermally conductive heat dissipator.

Another aspect of the present invention provides an electronic package including a thermally conductive plate, extended portions, and a transmission circuit. The thermally conductive plate has a first surface and a second surface, with the extended segments disposed on and thermally coupled to the first surface of the thermally conductive plate. The transmission circuit defines a cavity, and includes a first conductive layer, a second conductive layer, and a dielectric layer sandwiched between the first and second conductive layers. The second conductive layer is coupled to the second surface of the thermally conductive plate and the cavity extends through the transmission circuit to the thermally conductive plate.

Yet another aspect of the present invention provides an electronic package including a thermally conductive heat dissipator, a transmission circuit, and a semiconductor device. The thermally conductive heat dissipator has a first surface and a second surface with the first surface of the thermally conductive heat dissipator including extended portions. The transmission circuit defines a cavity, and includes a first conductive layer, a second conductive layer, and a dielectric layer sandwiched between the first and second conductive layers. The semiconductor device is thermally coupled to the thermally conductive heat dissipator. The second conductive layer is coupled to the second surface of the thermally conductive heat dissipator and the cavity extends through the transmission circuit to the thermally conductive heat dissipator.

The foregoing and other features and advantages of the invention will become further apparent from the following detailed description of the presently preferred embodiment, read in conjunction with the accompanying drawings. The scope of the invention is defined by the appended claims and equivalents thereof, the detailed description and drawings being merely illustrative of the invention rather than limiting the invention.

### BRIEF DESCRIPTION OF THE DRAWINGS

FIG. 1 is a schematic diagram of a conventional electronic package;

FIG. 2 is a schematic diagram of an electronic package according to an embodiment of the present invention;

FIG. 3 is an isometric diagram of an electronic package according to the present invention;

FIG. 4 is a schematic diagram of an electronic package according to another embodiment of the present invention; and

FIG. 5 is a schematic diagram of a thermal resistance network model for analysis of an electronic package made in accordance with the present invention.

### DETAILED DESCRIPTION OF THE PRESENTLY PREFERRED EMBODIMENT

Throughout the specification, and in the claims, the term “connected” means a direct connection between components or devices that are connected without any intermediate devices. The term “coupled” means either a direct connection between components or devices that are connected, or an indirect connection through one or more passive or active intermediary devices.

The present invention relates to electronic packages and, more particularly, to a package having improved thermal performance. The present invention allows an electronic package to transfer heat efficiently from the contents of the electronic package to the ambient atmosphere.

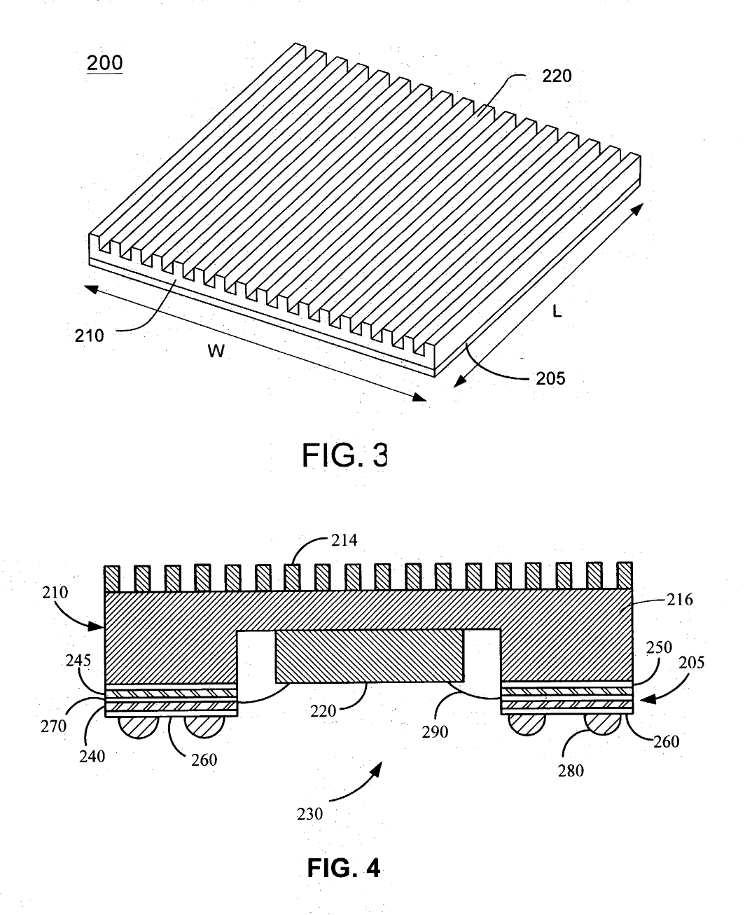

FIG. 2 is a schematic diagram of an electronic package made in accordance with the present invention. In this example, electronic package 200 is implemented as a tape ball grid array (TBGA) package.

Referring to FIG. 2, the electronic package 200 includes a transmission circuit 205 connected to a heat dissipator 210 with an adhesive layer 250, and a chip mounting cavity 230 defined by the transmission circuit 205 and heat dissipator 210. The transmission circuit 205 is typically flexible. In other embodiments, the transmission circuit 205 is semi-rigid or rigid. The transmission circuit 205 transmits information signals, power signals, power, grounds, or other electrical signals as desired for a particular application.

Heat dissipator 210 includes extended portions 212 as part of an exterior surface of heat dissipator 210. The extended portions 212 are also referred to as fins. In one embodiment, the extended portions 212 are an integral part of the heat dissipator 210. In other embodiments, the extended portions 212 are manufactured separately and then applied, forming the heat dissipator 210. Transmission circuit 205 includes a flexible dielectric layer 270 having a first conductive layer 240 on a first side, and a second conductive layer 245 on a second side.

Chip mounting cavity 230 is defined by transmission circuit 205 and heat dissipator 210. The chip mounting cavity 230 is typically formed by removing material from the heat dissipator 210, such as removal by etching or machining. In other embodiments, the chip mounting cavity 230 is created while fabricating the heat dissipator 210, such as while casting or molding the heat dissipator 210. In one embodiment, the chip mounting cavity 230 extends through the transmission circuit 205 into the heat dissipator 210. In another embodiment, the chip mounting cavity 230 only extends through the transmission circuit 205, and not into the heat dissipator 210.

Heat dissipator 210 is bonded to transmission circuit 205 by an adhesive 250, such as a commercially available thermoset adhesive. The heat dissipator 210 is also referred to as a heat dissipation layer. Flexible dielectric layer 270 is typically implemented as a polyimide film.

Heat dissipator 210 conducts and dissipates heat, as well as supporting transmission circuit 205. The heat dissipator 210 is made of any material having good thermal conductivity. In one example, heat dissipator 210 is manufactured from copper material. In another example, first conductive layer 240 and second conductive layer 245 are manufactured from copper material as well.

In the embodiment illustrated in FIG. 2, electronic package 200 additionally includes a semiconductor device 220, coating 260, solder balls 280, and wirebond connections 290. Semiconductor device 220 is mounted on heat dissipator 210 by any means known in the art. The semiconductor device 220 is also referred to as a die. In one example, semiconductor device 220 is mounted on heat dissipator 210 utilizing adhesive. The support provided by heat dissipator 210 enhances planarity for solder ball 280 attachments, such as to a printed circuit board (PCB).

Semiconductor device 220 is mounted in chip mounting cavity 230 and is wirebonded to first conductive layer 240, second conductive layer 245, and flexible dielectric layer 270. Wirebond connection 290 illustrates an exemplary connection between the semiconductor device 220 and flexible dielectric layer 270. In one embodiment, semiconductor device 220 is encapsulated within chip mounting cavity 230 utilizing a dam and fill material. In another example, semiconductor device 220 is encapsulated within chip mounting cavity 230 utilizing an encapsulation material.

Extended portions 212 are manufactured as a part of the exterior surface of heat dissipator 210. Extended portions 212 enhance heat transfer from the electronic package 200 to the ambient atmosphere by increasing the surface area available for heat transfer. One way to increase the surface area of the heat dissipator 210 is to increase the height of individual extended portions 212. The extended portions 212 may be any size and shape that will increase the surface area of the heat dissipator 210, such as rectangles, cylinders, pins, or pyramids, having rectangular, circular, semi-circular, elliptical, semi-elliptical, or triangular cross section. The extended portions 212 may be elongate with their axes parallel to the surface of the heat dissipator 210 or with their axes projecting from the surface of the heat dissipator 210.

FIG. 3, in which like elements share like reference characters with FIG. 2, is an isometric diagram of an electronic package 200 according to the present invention. Electronic package 200 includes heat dissipator 210 with extended portions 220, and transmission circuit 205. Electronic package 200 illustrates one embodiment of the present invention wherein the extended portions 220 are rectangular.

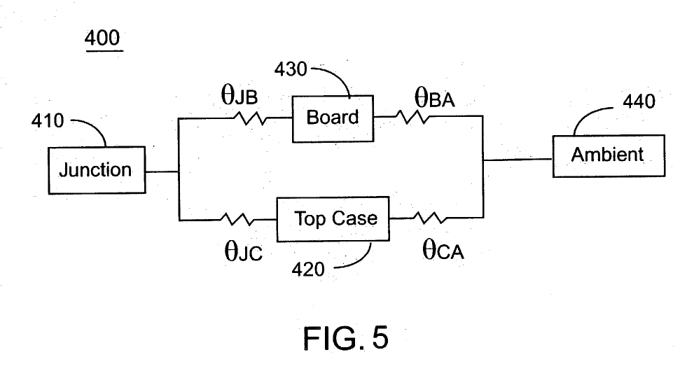

Heat transfer from within the electronic package depends upon the total surface area of the heat dissipator 210. The total surface area is also referred to as total top surface area. The total surface area is the product of length L and width W of the heat dissipator 210, plus the area of the extended portions 220 perpendicular to the surface of the heat dissipator 210. The extended portions 220 provide additional surface area to the heat dissipator 210 to increase the surface area available for heat transfer. The thermal effect of the additional surface area is discussed in conjunction with FIG. 5 below.

FIG. 4, in which like elements share like reference characters with FIG. 2, is a schematic diagram of an electronic package according to another embodiment of the present invention. Extended segments 214 are manufactured separately and disposed on thermally conductive plate 216 to form the heat dissipator 210. The extended segments 214 are connected to the thermally conductive plate 216 by thermally conductive adhesive bonding, soldering, brazing, welding, or any method providing thermal continuity between the extended segments 214 and thermally conductive plate 216.

Extended segments 214 enhance heat transfer from the electronic package to the ambient atmosphere by increasing the surface area available for heat transfer. The extended segments 214 may be any size and shape that will increase the surface area of the heat dissipator 210, such as rectangles, cylinders, pins, or pyramids, having rectangular, circular, semi-circular, elliptical, semi-elliptical, or triangular cross section. The extended segments 214 may be elongate with their axes parallel to the surface of the heat dissipator 210 or with their axes projecting from the surface of the heat dissipator 210.

In certain embodiments, the individual extended segments 214 can be interconnected to maintain spacing between the individual extended segments 214 and make assembly more convenient. For example, the individual extended segments 214 can be interconnected with a web, grid, bars, or other interconnections. In another example, the individual extended segments 214 are interconnected to maintain spacing until the extended segments 214 are installed on the thermally conductive plate 216, and then the interconnections removed. For example, the individual extended segments 214 can be interconnected with tape during installation and the tape removed after the extended segments 214 are connected to the thermally conductive plate 216.

FIG. 5 is a schematic diagram of a thermal resistance network model for analysis of an electronic package made in accordance with the present invention. The thermal resistance network 400 represents thermal effects of key components within an electronic device and the key components' ability to transfer heat from the electronic package to the ambient atmosphere. The thermal resistance network model is utilized to evaluate the impact of varying configurations of the heat dissipation plate.

Referring to FIG. 5, thermal resistance network 400 includes junction element 410, top case element 420, board element 430, and ambient element 440. Junction element 410 represents internal elements of the electronic device. Top case element 420 represents the dissipation plate of the electronic package. Board element 430 represents the printed circuit board on which the electronic package is mounted. Ambient element 440 represents the ambient atmosphere surrounding the electronic package. Thermal resistance network 400 further includes junction to board thermal resistance θ_{JB}, junction to top case thermal resistance θ_{JC}, board to ambient thermal resistance θ_{BA}, and top case to ambient thermal resistance θ_{CA}.

Thermal resistance network 400 models two parallel paths by which heat is transferred from the electronic device mounted in the electronic package to the ambient atmosphere. Heat is transferred from electronic device to the ambient atmosphere through both the heat dissipation plate path and the printed circuit board (PCB) path.

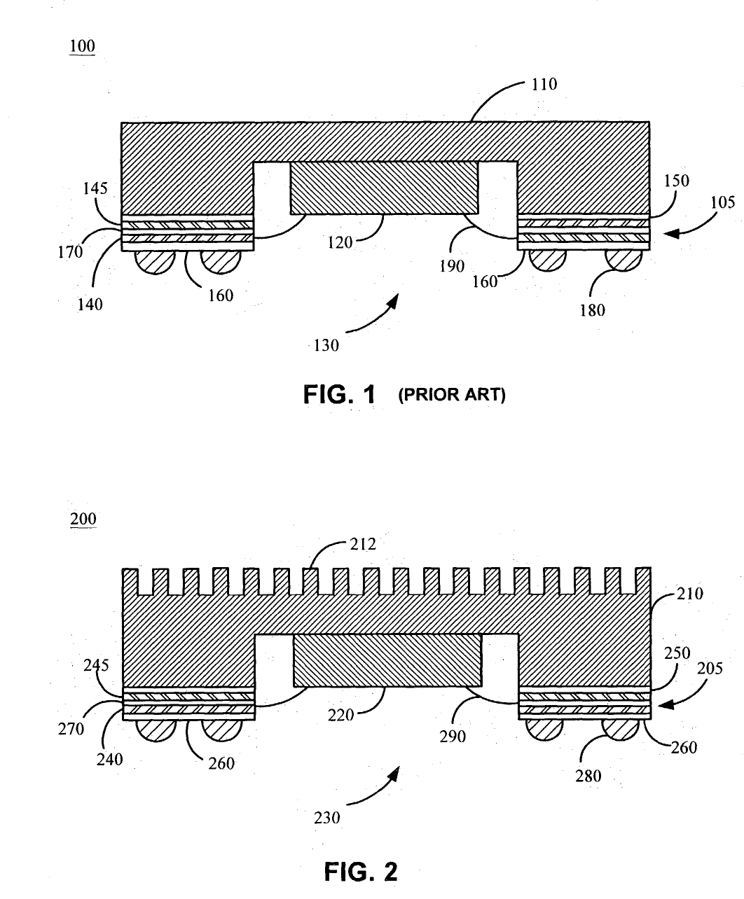

To model the electronic package of FIG. 1 above as the baseline simulation, heat is transferred from the semiconductor device 120 mounted in the chip mounting cavity 130 in electronic package 100 to the ambient atmosphere via heat dissipation plate 110. Heat is also transferred from the semiconductor device 120 through the transmission circuit 105 to the ambient atmosphere via a printed circuit board (not shown). Junction element 410 of FIG. 5 represents the semiconductor device 120 of FIG. 1. Top case element 420 of FIG. 5 represents the heat dissipation plate 110 of FIG. 1.

To model the electronic package of FIG. 2 above as the baseline simulation, heat is transferred from the semiconductor device 220 mounted in the chip mounting cavity 230 in electronic package 200 to the ambient atmosphere via heat dissipator 210. Heat is also transferred from within the electronic package 200 through the transmission circuit 205 to the ambient atmosphere via a printed circuit board (not shown). Junction element 410 of FIG. 5 represents the semiconductor device 220 of FIG. 2. Top case element 420 of FIG. 5 represents the heat dissipator 210 of FIG. 2.

Referring to FIG. 5, heat generated by the semiconductor device is primarily transferred to the ambient atmosphere by the two paths modeled in thermal resistance network 400. The modeling allows the thermal resistance of the branch including the board element 430 to be held constant, while the thermal resistance of the branch including the top case element 420 is varied. This models the effect of the top case element 420 on the thermal resistance network 400.

Implementation of the present invention improves the thermal resistance of thermal resistance network 400, also referred to as total thermal resistance θ_{JA}, by reducing the top case to ambient thermal resistance θ_{CA}. Modeling of the heat dissipation plate includes determining the top case to ambient thermal resistance θ_{CA}, as well as the junction to top case thermal resistance θ_{JC}.

The total thermal resistance θ_{JA} of the thermal resistance network 400 can be expressed as:

$${θ}_{JA} = \frac{1}{\frac{1}{[ {θ}_{JB} + {θ}_{BA} ]} + \frac{1}{[ {θ}_{JC} + {θ}_{CA} ]}}$$

where the top case to ambient thermal resistance θ_{CA} is defined as:

$${θ}_{CA} = \frac{1}{hA}$$

where h is the convection heat transfer coefficient, which is a function of the material of the heat dissipation plate and the surrounding ambient atmosphere. A is the total top surface area of the heat dissipation plate of the electronic package.

The present invention increases the total top surface area A, thereby decreasing the top case to ambient thermal resistance θ_{CA}. The total thermal resistance θ_{JA} of the thermal resistance network 400 decreases as the top case to ambient thermal resistance θ_{CA} decreases. This results in the electronic package of the present invention having increased thermal performance.

A quarter model simulation, utilizing common features of existing tape ball grid array (TBGA) packaging, was conducted for the conventional electronic package of FIG. 1 as a baseline and for the present invention as shown in FIG. 2. The simulation was performed using I-deas simulation software, a commercial computer simulation software produced by SDRC (Structural Dynamics Research Corporation).

The baseline simulation for the electronic package of FIG. 1 assumed a JEDEC STANDARD (EIA/JESD 51-3 “Low Effective Thermal Conductivity Test Board for Leaded Surface Mount Packages”) printed circuit board (PCB) as the test board, and included the following parameters: package size (33×33 mm), die size (9.2×9.2 mm), ball count (400), ball pitch (1.27 mm), ball diameter (0.76 mm), spreader thickness (0.73 mm), natural convection thermal flow rate (0 m/s), ambient temperature (25 C.), thermal conductivity (360 W/mK), and power provided (4 W).

The invention simulation for the electronic package of FIG. 2 used the common features of existing tape ball grid array (TBGA) packaging of the baseline simulation and added the extended portions 212 to the heat dissipator 210. The invention simulation assumed each extended portion 212 to be 1 mm in height, 1 mm in width, and to extend the length of the electronic package as shown in FIG. 3. Additionally, each extended portion 212 is separated from the nearest extended portion 212 by 1 mm.

The baseline simulation for the electronic package of FIG. 1 results in a total thermal resistance θ_{JA} of 12.2 W/C, while the invention simulation for the electronic package of FIG. 2 results in a total thermal resistance θ_{JA} of 8.25 W/C. This is an improvement in the total thermal resistance θ_{JA} of 32.4%. Thermal resistance can be further improved by further increasing the total top surface area of the electronic package. In one embodiment, the total top surface area of the electronic package is increased by increasing the height of extended portions.

The above-described electronic package having improved thermal performance is an exemplary package, illustrating one possible approach for improving thermal performance. The actual implementation may vary from the electronic package discussed. Moreover, various other improvements and modifications to this invention may occur to those skilled in the art, and those improvements and modifications will fall within the scope of this invention as set forth in the claims below.

The present invention may be embodied in other specific forms without departing from its essential characteristics. The described embodiments are to be considered in all respects as illustrative only and not considered as restrictive.

We claim:

1. An electronic package comprising:
a thermally conductive heat dissipator, the thermally conductive heat dissipator having a first surface and a second surface, the first surface of the thermally conductive heat dissipator including extended portions; and
a transmission circuit, the transmission circuit defining a cavity, and including a first conductive layer, a second conductive layer, and a dielectric layer sandwiched between the first and the second conductive layers;
wherein the second conductive layer is coupled to the second surface of the thermally conductive heat dissipator, and the cavity extends through the transmission circuit to the thermally conductive heat dissipator.

2. The electronic package of claim 1 wherein the transmission circuit is selected from the group consisting of a flexible transmission circuit, a semi-rigid transmission circuit, and a rigid transmission circuit.

3. The electronic package of claim 1 wherein at least one of the extended portions has a cross section selected from the group consisting of rectangular, circular, semi-circular, elliptical, semi-elliptical, and triangular.

4. The electronic package of claim 1 further comprising:
a semiconductor device, the semiconductor device located in the cavity and mounted on the second surface of the thermally conductive heat dissipator.

5. The electronic package of claim 1 wherein the thermally conductive heat dissipator defines a cavity aligned with the cavity defined by the transmission circuit.

6. The electronic package of claim 5 further comprising:
a semiconductor device, the semiconductor device located in the cavity defined by the thermally conductive heat dissipator.

7. An electronic package, comprising:
a thermally conductive plate, the thermally conductive plate having a first surface and a second surface;
extended segments, the extended segments disposed on and thermally coupled to the first surface of the thermally conductive plate; and
a transmission circuit, the transmission circuit defining a cavity, and including a first conductive layer, a second conductive layer, and a dielectric layer sandwiched between the first and the second conductive layers;
wherein the second conductive layer is coupled to the second surface of the thermally conductive plate, and the cavity extends through the transmission circuit to the thermally conductive plate.

8. The electronic package of claim 7 wherein the transmission circuit is selected from the group consisting of a flexible transmission circuit, a semi-rigid transmission circuit, and a rigid transmission circuit.

9. The electronic package of claim 7 wherein at least one of the extended segments has a cross section selected from the group consisting of rectangular, circular, semi-circular, elliptical, semi-elliptical, and triangular.

10. The electronic package of claim 7 wherein the method of thermally coupling the extended segments to the first surface of the thermally conductive plate is a selected from the group consisting of adhesive bonding, soldering, brazing, and welding.

11. The electronic package of claim 7 further comprising:
a semiconductor device, the semiconductor device located in the cavity and coupled to the second surface of the thermally conductive plate.

12. The electronic package of claim 7 wherein the thermally conductive plate defines a cavity aligned with the cavity defined by the transmission circuit.

13. The electronic package of claim 12 further comprising:
a semiconductor device, the semiconductor device located in the cavity defined by the thermally conductive plate.

14. An electronic package comprising:
a thermally conductive heat dissipator, the thermally conductive heat dissipator having a first surface and a second surface, the first surface of the thermally conductive heat dissipator including extended portions;
a transmission circuit, the transmission circuit defining a cavity, and including a first conductive layer, a second conductive layer, and a dielectric layer sandwiched between the first and the second conductive layers; and
a semiconductor device, the semiconductor device being thermally coupled to the thermally conductive heat dissipator;
wherein the second conductive layer is coupled to the second surface of the thermally conductive heat dissipator, and the cavity extends through the transmission circuit to the thermally conductive heat dissipator.

15. The electronic package of claim 14 wherein the transmission circuit is selected from the group consisting of a flexible transmission circuit a semi-rigid transmission circuit, and a rigid transmission circuit.

16. The electronic package of claim 14 wherein at least one of the extended portions has a cross section selected from the group consisting of rectangular, circular, semi-circular, elliptical, semi-elliptical, and triangular.

17. The electronic package of claim 14 wherein the semiconductor device is located in the cavity defined by the transmission circuit.

18. The electronic package of claim 14 wherein the thermally conductive heat dissipator defines a cavity aligned with the cavity defined by the transmission circuit.

19. The electronic package of claim 18 wherein the semiconductor device is located in the cavity defined by the thermally conductive heat dissipator.
